(19) United States
(12) Patent Application Publication
(10) Pub. No.: US 2020/0212536 A1
(43) Pub. Date: Jul. 2, 2020

(54) WIRELESS COMMUNICATION DEVICE WITH ANTENNA ON PACKAGE

(71) Applicant: Texas Instruments Incorporated, Dallas, TX (US)

(72) Inventors: Vikas Gupta, Dallas, TX (US); Sadia Naseem, Dallas, TX (US); Meysam Moallem, Plano, TX (US)

(21) Appl. No.: 16/404,810

(22) Filed: May 7, 2019

Related U.S. Application Data
(60) Provisional application No. 62/787,080, filed on Dec. 31, 2018.

(51) Int. Cl. H01Q 1/22; H01Q 1/38; H01Q 1/40; H01L 21/48; H01L 23/498; H01L 23/00; H01L 23/66

(52) U.S. Cl. CPC H01Q 1/2283; H01L 2224/95001; H01Q 1/40; H01L 21/481; H01L 23/49827; H01L 24/24; H01L 23/66; H01L 24/08; H01L 24/96; H01L 24/25; H01L 2223/6677; H01L 2224/08225; H01L 2224/24137; H01L 2224/24195; H01L 2224/24155; H01L 2224/25171; H01Q 1/38

(57) ABSTRACT

In a described example, a wireless communication device includes an antenna substrate having an antenna on an antenna side surface; a semiconductor die on an device side surface of the antenna substrate, opposite the antenna side surface; and an antenna protection layer covering the antenna and a portion of the antenna side surface of the antenna substrate having a uniform predetermined thickness across the antenna side surface of the antenna substrate within +/−10%.

### CROSS REFERENCE TO RELATED APPLICATIONS

This application claims the benefit under 35 U.S.C. § 119(e) to co-owned U.S. Provisional Patent Application Ser. No. 62787080, filed Dec. 31, 2018, titled “WIRELESS COMMUNICATION DEVICE WITH ANTENNA ON PACKAGE,” which is hereby incorporated by reference in its entirety herein.

### TECHNICAL FIELD

This disclosure relates generally to wireless communication systems, and more particularly to wireless communication devices with antennas.

### BACKGROUND

Wireless communications devices and systems communicate with one another using a radio transceiver (including a receiver and a transmitter) connected to an antenna.

The transmitter typically includes a data modulation stage, one or more intermediate frequency stages, and a power amplifier. The data modulation stage converts raw data into baseband signals in accordance with a particular wireless communication standard. The intermediate frequency (IF) stages mix the baseband signals with one or more local oscillations to produce radio frequency (RF) signals. The power amplifier amplifies the RF signals prior to transmission via the antenna.

The receiver is coupled to the antenna and includes a low noise amplifier, one or more IF stages, a filtering stage and a data recovery stage. The low noise amplifier receives inbound RF signals via the antenna and amplifies them. The IF stages mix the amplified RF signals with one or more local oscillators to convert the amplified RF signals into baseband signals or IF signals. The filtering stage filters the baseband signals of IF signals to attenuate unwanted out of band signals to produce filtered signals. The data recovery stage recovers raw data from the filtered signals in accordance with particular wireless communication standard.

Antenna design and performance is important in wireless communication systems. The impedance of the antenna is designed to match the impedance of the RF sending and receiving circuits in the transceiver for optimal performance. Any variation in the impedance of the antenna that results in impedance mismatch to the sending and receiving circuits in the transceiver reduces performance of the wireless communication system.

In an antenna formed on a package, the antenna is covered with an antenna protective layer to protect the antenna. The antenna protective layer impacts the resonant frequency of the antenna and the resonant frequency and impedance of the antenna is a function of the material used for the protective layer and of the material thickness. The protective layer over the antenna reduces the antenna frequency bandwidth, and can increase loss if the material is a lossy material. It is desirable for the antenna protection layer to have a dielectric constant less than about 5 and preferably less than 4 to minimize the impact on the antenna bandwidth. Current methods of applying the antenna protective layer include laminating a film onto the antenna side of the antenna substrate, and squeegeeing a liquid protective layer followed by photo or thermal curing. Deposition of the antenna protection layer using film lamination or deposition using a squeegee process limits the minimum protective film thickness to about 15 μm and limits the thickness variation to +/−30% or more. Variation in the film thickness results in non-uniform performance of the antennas between devices.

In devices that include an antenna-on-package (AOP), the antennas are formed on a substrate. Antennas formed on packages are used to reduce the device form factor and overall cost (when compared to the use of discrete antennas). AOPs are used when the antennas are small enough to fit on the package, such as small enough to fit in an integrated circuit package.

In producing antennas on substrates, the antenna substrates are initially joined together by saw streets to form an antenna substrate strip. After the antennas are formed, the antenna side of the antenna substrate strip is coated with the antenna protection layer prior to the antenna substrates being singulated from one another. The antenna substrate strip is separated into individual singulated antenna substrates, for example by cutting or sawing the antenna substrate strip. The singulated antenna substrates can be mounted on another substrate, such as a printed circuit board (PCB), to form a wireless communications device. Other components such as integrated circuit chips, resistors, transformers, and capacitors can be mounted on the non-antenna side of the antenna substrate strip prior to singulating the antenna substrates and mounting them on communication device PCBs.

### SUMMARY

In a described example, a wireless communication device includes an antenna substrate having an antenna on an antenna side surface; a semiconductor die on an device side surface of the antenna substrate, opposite the antenna side surface; and an antenna protection layer covering the antenna and a portion of the antenna side surface having a predetermined thickness across the antenna side surface of the antenna substrate within +/−10%.

### BRIEF DESCRIPTION OF THE DRAWINGS

FIGS. 1 and 2 are cross sectional views of wireless communication devices.

FIGS. 3A and 3B are cross sectional views illustrating methods of coating antennas with an antenna protection layer.

FIG. 4 is a flow diagram of steps for coating antennas with an antenna protection layer.

FIGS. 5A through 5F are cross sections of major steps to form the wireless communication system shown in FIG. 1

FIG. 6 is a flow diagram describing an example method for forming the cross sections shown in FIGS. 5A through 5F.

FIGS. 7A-7K illustrate in a series of cross section major steps to form a wireless communications system using a fan-out wafer level processing (FOWLP) arrangement.

FIG. 8 is a flow diagram describing an example method to form the FOWLP arrangement of FIGS. 7C through 7H.

### DETAILED DESCRIPTION

Corresponding numerals and symbols in the different figures generally refer to corresponding parts unless otherwise indicated. The figures are not necessarily drawn to scale.

In this description, the term “semiconductor die” is used. As used herein, the term “semiconductor die” means a die formed using semiconductor material. Examples include dies containing integrated circuits, where several and sometimes hundreds or thousands of transistors are formed and are coupled together using patterned conductors to perform a desired function. An example function is a transceiver. Additional examples include dies including passive devices such as resistors, capacitors, inductors and diodes formed on a semiconductor substrate. Discrete devices such as one, or a few, power field effect transistors (FETs), bipolar junction transistors (BJTs), rectifiers, and amplifiers formed on semiconductor substrates are also examples of semiconductor dies. Analog-to-digital converters, RF filters, transceivers, photocells, photodiodes, digital micromirror devices (DMDs), and transformers are additional examples of semiconductor dies. As used herein, a “packaged semiconductor device” is a semiconductor die that has been mounted on a substrate with leads or terminals for making electrical connections, and which is wholly or partially covered by a protective package. In an example packaged semiconductor device, mold compound covers all or portions of the semiconductor die and leads coupled to the semiconductor die.

In this description, the term “ink jet deposition” is used for an example process of depositing material. As used herein, the term “ink jet deposition” means depositing material from a liquid in a reservoir that feeds a nozzle. Deposition is performed by forming drops in response to an electrical signal as the nozzle is moved with respect to a surface (or alternatively as the surface moves with respect to the nozzle). An ink jet deposition tool may have tens, hundreds or more nozzles. In a printing application, the material is ink, and the ink jet deposition process is referred to as “ink jet printing”. In deposition of materials in manufacturing, the liquid to be deposited can be referred to as “ink” and as used herein the term “ink” can include solder, dielectrics, conductive materials, adhesives, and polymers as used in the arrangements. Ink jet deposition allows precise placement of material by using “drop on demand” (DOD) technology, where a reservoir of the liquid has a nozzle, and a small volume of the liquid is forced from the nozzle in response to an electrical signal. The liquid forms a drop as it falls vertically onto a surface. In this description, the term “ink residue” is used. Ink residue is material deposited in liquid form by ink jet deposition or by screen deposition that may then be cured to form a solid layer, and the material is referred to herein as “ink residue.” The ink jet deposition in the arrangements can be used to deposit multiple layers so that a thin layer can be additively deposited over prior ink residue layers to form a thicker layer of material. The precision of the ink jet deposition tool allows deposition of the liquid material in some areas and not in others as the tool traverses across the surface (or if the tool is fixed, as the surface moves beneath the tool). The reservoir can include a piezo-electric actuator that expels a known volume of ink through a nozzle in response to an electrical signal, or in a thermal ink jet deposition tool, the liquid can be heated quickly by a resistive element in the reservoir and expand, forcing a known volume of liquid through the nozzle. The liquid forms drops that travel vertically to land on the surface that the material is deposited on. Because the material can be very accurately placed even in small areas, no etch or material removal step is needed to remove ink residue material after the ink jet deposition. Also, the material is used very efficiently with little waste when compared to spin coating, squeegee coating, screen deposition (sometimes referred to as “screen printing”) or slit print deposition processes.

In this description, the term “predetermined thickness” is used in reference to a deposited protection layer. As used herein, a predetermined thickness is a designed thickness for a layer. In this description, the term “uniform predetermined thickness” is used. As used herein, a “uniform predetermined thickness” is a designed thickness for a layer that varies only slightly, for example, a layer having a predetermined thickness that varies less than +/−10% over the entire area of the layer is a layer with “uniform predetermined thickness.”

In the arrangements, the problem of antenna uniformity and control of antenna characteristics is solved by controlling thickness of an antenna protective layer deposited over antennas. In an example arrangement, the antenna protective layer is formed by ink jet deposition of an ink residue material. In another example arrangement, a screen deposition process leaves an ink residue layer as the antenna protective layer.

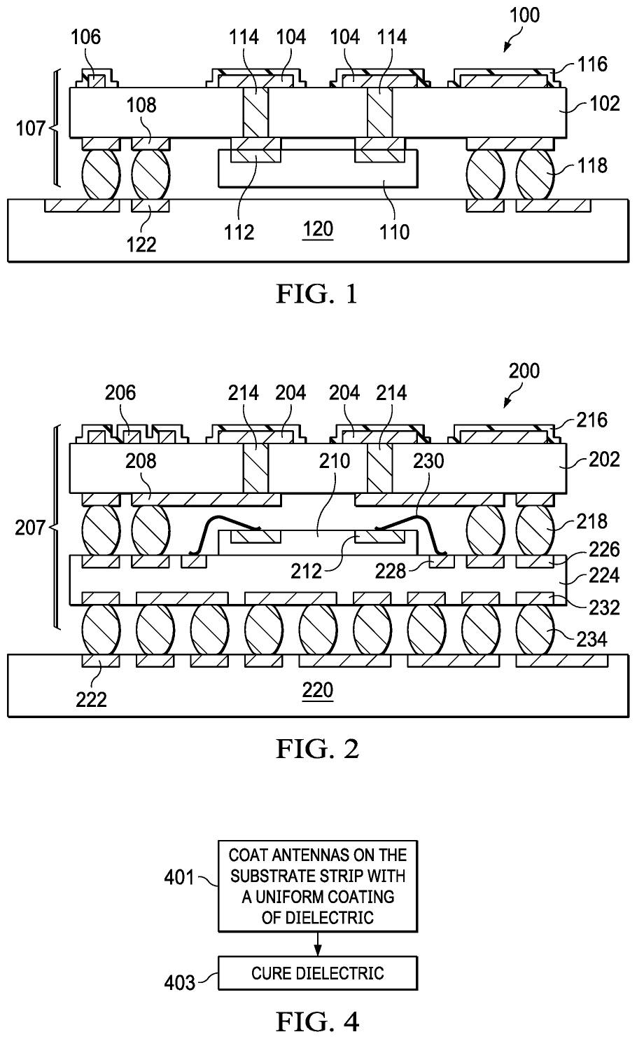

FIG. 1 shows a wireless communication device 100 which includes two antennas 104. The antennas 104, which transmit and/or receive wireless RF signals, are formed over the surface of antenna substrate 102. The antenna substrate 102 can be a molded interconnect substrate (MIS); a pre-molded lead frame (PMLF) with lead frame conductors and mold compound in a preformed structure; a tape based or film-based substrate carrying conductors; a laminate substrate with multiple layers of conductors and insulator layers; and a printed circuit board substrate of ceramic, fiberglass, resin, or a glass fiber reinforced epoxy substrate such as FR4. Additional electrical leads 106 may also be formed on the surface of the antenna substrate 102. The antenna side of the antenna substrate102 including any additional leads 106 is at least partially covered with an antenna protection layer 116. The antenna protection layer 116 is a dielectric material. Useful materials for the arrangements are dielectrics such as polyimide or polybenzoxazole (PBO).

In the wireless communication device 100 shown in FIG. 1, a wireless communication module 107 is mounted on a wireless communication substrate 120. Semiconductor die 110 is mounted on the device side of the antenna substrate 102, opposite the antenna side. Bond pads 112 on the semiconductor device 110 are connected to the antenna 104 by filled through substrate vias 114. In an alternative example, conductors can be formed at the periphery of the substrate 102 and extending between the surfaces to form connections between the antenna side and the device side without the use of through substrate vias. The semiconductor die 110 can be a transceiver that sends RF signals to the antennas 104 for transmission and receives incoming RF signals from the antennas 104. Other components such as other packaged IC systems, inductors, filters, resistors, capacitors, and transformers can also be mounted on the antenna substrate 102.

Solder balls 118 connect electrical leads 108 on the non-antenna side of the antenna substrate 102 to electrical leads 122 on a wireless communication system on second substrate 120 forming the wireless communication system 100. The second substrate 120 can be any of the substrate materials described hereinabove with respect to the antenna substrate, and can be a semiconductor wafer or portion thereof, or another semiconductor die. Because the semiconductor die 110 is carried on the underside of antenna substrate 102, the arrangement is sometimes referred to as a “possum” package for the semiconductor die 110. The semiconductor die 110 may be a wireless transceiver, transmitter, receiver or other wireless communication circuit.

FIG. 2 shows another example wireless communication device 200. The antennas 204 which transmit and receive wireless RF signals are formed on the surface of antenna substrate 202. The surface of the antenna substrate 202 and the antennas 204 are at least partially covered with antenna protection layer 216. Vias such as filled through vias 214 vertically connect the antennas 204 to leads 208 on the non-antennas side of the antenna substrate 202.

In the wireless communication device 200, a wireless communication module 207 is formed by a first set of ball bonds 218 that connects leads 208 on the non-antenna side of the antenna substrate 202 to leads 226 on a circuit substrate 224. In FIG. 2 a semiconductor die 210 is mounted on the circuit substrate 224. Wirebonds 230 electrically connect bondpads 212 on the semiconductor die 210 to leads 228 on the circuit substrate 224. The leads 226 on the circuit substrate 224, and the ball bonds 218 between these leads 226 and the antenna leads 208 on the antenna substrate 202, electrically couple the semiconductor die 210 to the antennas 204, in the wireless communication module 207 In an alternative arrangement, the semiconductor die 210 can be flip chip mounted to the circuit substrate 224 using copper pillar bumps or solder bumps, instead of wirebonds 230, to make an electrical connection between the bondpads 212 and leads 228.

In this wireless communication device 200, a second set of ball bonds 234, which can be solder balls or copper balls, pillars or bumps, electrically connects leads 232 on the non-antenna side of the circuit substrate module 207 to leads 222 on a wireless communication substrate 220, forming the wireless communications device 200.

FIGS. 1 and 2 are but two examples of wireless communications systems. There is a multitude of other wireless communication system arrangements. In another example arrangement, a wafer level processing (WLP) fanout arrangement (FOWLP) includes one or more antennas formed over a redistribution layer (RDL) formed over a transceiver die. The redistribution layer provides signal fanout, including antenna leads extending from the transceiver die. Common to all wireless communications systems are antennas covered with an antenna protection layer.

The performance of a wireless communication device or system is sensitive to the impedance matching between the antenna(s) and the transceiver circuits. One important component that impacts antenna impedance is an antenna protection layer. The antenna protection layer attenuates transmitted and received RF signals and reduces the antenna bandwidth. During design and development of the wireless communication system, the impedance of the communications system circuitry is matched to the impedance of the antenna. Any change in the thickness of the antenna protection layer from the target thickness changes the antenna bandwidth and, hence, degrades the performance of the wireless communication system. The change in thickness of the antenna protection layer between individual wireless communication systems over a manufacturing run can cause the performance distribution across the individual wireless communication systems in the manufacturing run to broaden. Wireless communications systems in the tail of the performance distribution can fail a performance specification, resulting in costly scrap. Further, variations in the thickness obtained between different manufacturing runs may require tuning after the systems are produced to create uniform performance within a specified performance criteria. Tuning adds costs to the manufacture of the systems.

In arrangements for wireless communication devices, the antenna protection layer is deposited with a thickness in the range of 2 μm to 100 μm and with a thickness variation of less than +/−10%. While a thin layer is desireable, layers less than 2 μms may not be sufficient to protect the antennas and to form a controllable thickness. Layers greater than 100 μms will attenuate the signals, which is undesirable. A layer of thickness between 2 and 100 μms has sufficient thickness for the needed antenna protection and yet is thin enough to provide low signal attenuation. The arrangements herein provide for uniformity in the thickness of the layer, which is advantageous because devices produced by the arrangements will have the same performance, a requirement for efficient and low cost manufacture. An antenna protection layer with a thickness of 10 μm or less is preferred for reduced negative impact on RF bandwidth. Other thicknesses in the range between 2 μm to 100 μms can be used depending on materials chosen for the antenna protection layer.

Example methods of deposition that enable antenna protection films with thicknesses of 10 μm or less and with thickness control of +/−10% or less include screen deposition and ink jet deposition. When ink jet deposition is utilized, thickness variation in the ink residue deposited of less than +/−0.2 μms can be achieved. Tightly controlled thickness variation narrows the distribution in performance across the individual wireless communication devices or systems produced within one manufacturing run and in between different manufacturing runs. This reduces scrap resulting from some of the wireless communication systems failing performance specifications.

The thinner antenna protection layer results in less signal attenuation. The thinner antenna protection layers obtained using the arrangements improve the performance of the wireless communication systems.

Example antenna protective layer materials useful with the arrangements include polyimide, polybenzoxazole (PBO), epoxies, resins, and solder mask or solder resist materials.

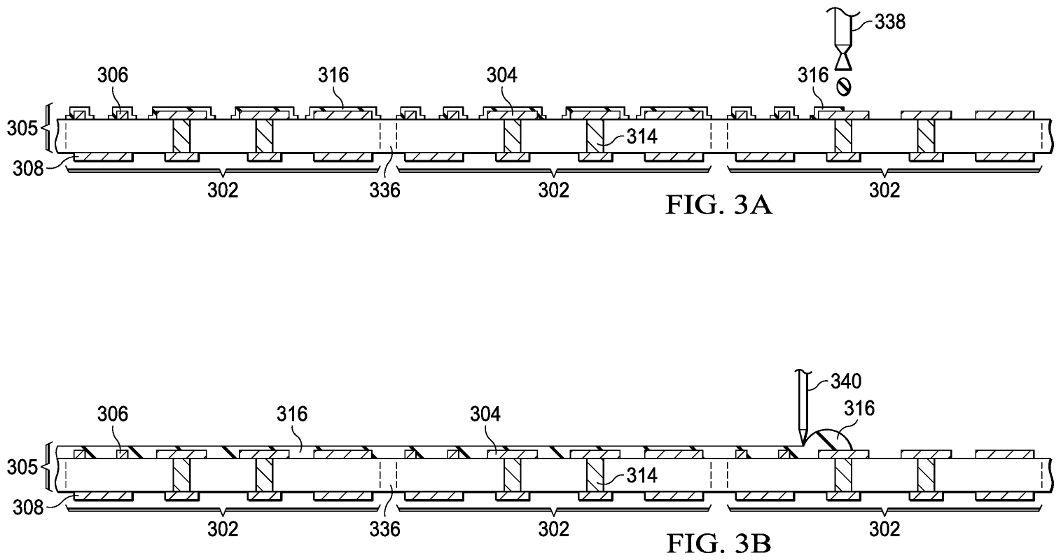

FIGS. 3A and 3B are cross sectional views that illustrate ink jet deposition and screen deposition methods for coating the antenna protection layer onto the antenna side of an antenna substrate. FIG. 4 is a flow diagram describing the major steps for these coating processes. In FIGS. 3A and 3B, similar reference labels are used for similar elements in FIG. 1, for clarity. For example, antenna substrate 302 in FIGS. 3A and 3B corresponds to antenna substrate 102 in FIG. 1.

FIG. 3A shows an antenna substrate strip 305 composed of three antenna substrates 302 joined together by saw streets 336. More or fewer antenna substrates 302 can be used with substrate strip 305. Each antenna substrate 302 has an antenna 304 formed on the surface as well as optional electrical leads 306. In the example shown, filled vias 314 connect the antenna 304 to electrical leads 308 on the non-antenna side of the antenna substrate 302. Other connections can be formed between the electrical leads 308 and the antenna 304, for example conductors formed on the peripheral edge of the antenna substrate 302 can couple antennas 304 to leads 308.

FIG. 3A (step 401 FIG. 4) illustrates the antennas 304 and the surface of the antenna substrate strip 305 being coated with an antenna protection layer 316 using ink jet deposition by ink jet tool 338. Examples of antenna protection layer materials that can be ink jet deposited include AUS 320 from Tayio America, Inc. and 830NSF-LC and 830NSF-LCA from Mitsubishi Gas Chemical Co., Inc. In one arrangement AUS 320 is deposited with a thickness of 3.0 μm+/−0.30 μm. After deposition, the antenna protection layer 316 is cured (step 403 FIG. 4). In the arrangement, AUS 320 is cured in an oven at a temperature of 150° C.-200° C. for a time of up to one hour. Alternatively, a photo curable polymer antenna protection layer can be ink jet deposited and cured with exposure to light. The antenna protection layer 316 can be formed by multiple passes of the ink jet deposition tool 338, each pass depositing a thinner layer of the material. Alternatively, a single pass deposition can be used. In one example a 2.0 μm antenna protection layer 316 is deposited using a single pass deposition with a thickness variation of +/−0.2 μm.

In an example, a 5 μm layer of antenna protection material was obtained by ink jet deposition of two layers. Each layer was targeted at approximately 2.4 μm. In another example, a 10 μm layer was obtained using ink jet deposition of four layers, with each layer targeted at approximately 2.4 μm. In both examples the average thickness deviation over many samples was 0.2 μm. Ink jet deposition deposits the antenna protection layer 316 very efficiently with little waste when compared to spin coating, squeegee coating, screen deposition or slit print deposition. In FIG. 3A, the surface of the antennas 304 and other leads 306 and the surface of the antenna substrate 305 for about 5 μm adjacent to the antennas 304 and leads 306 is covered with antenna protection layer 316. The remaining surface of the antennal substrate 305 is not covered saving costly antenna protection layer 316 material. Ink jet deposition generates very little hazardous waste.

In FIG. 3B (step 401 FIG. 4) the antennas 304 and the surface of the antenna substrate strip 305 are coated with an antenna protection layer 316 using screen deposition tool 340. Examples of antenna protection layer materials that can be screen deposited include AUS 320 from Tayio America, Inc. and 830NSF-LC and 830NSF-LCA from Mitsubishi Gas Chemical Co., Inc. In one arrangement AUS 320 is deposited with a thickness of 10 μm+/−1 μm. After deposition, the antenna protection layer 316 is cured (step 403 FIG. 4). AUS 320 is cured in an oven at a temperature of 150° C.-200° C. for a time of up to one hour. Alternatively, a photo curable polymer antenna protection layer can be screen deposited and the ink residue layer can be cured by exposure to light. In a particular example the photo curable polymer layer can be cured by exposure to ultra-violet (UV) light. The minimum thickness of the antenna protection layer 316 deposited using screen deposition or spin coating is about 5 μm with a tolerance of about +/−0.5 μm. Screen deposition and spin coating covers the entire surface of the antenna substrate 305 in addition to the surface of the antennas 304 and the leads 306. Screen and spin coating deposition processes waste about half or more of the antenna protection material 316. Ink jet deposition of the antenna protection layer 316 is preferred because it wastes almost none of the antenna protection layer 316 material. Ink jet deposition can deposit a thinner layer with less thickness variation than spin coating or screen deposition.

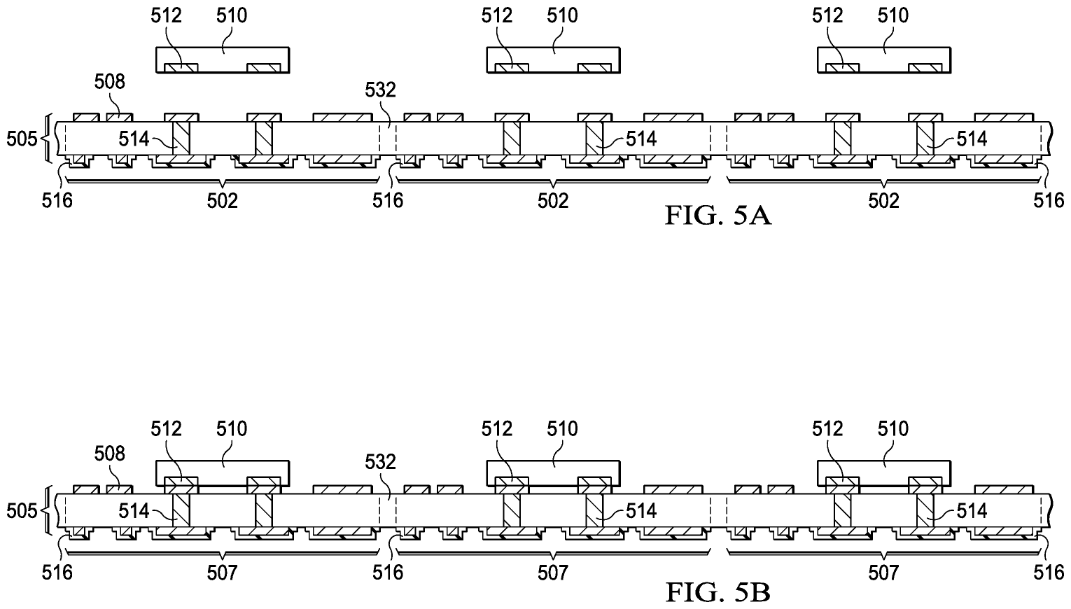

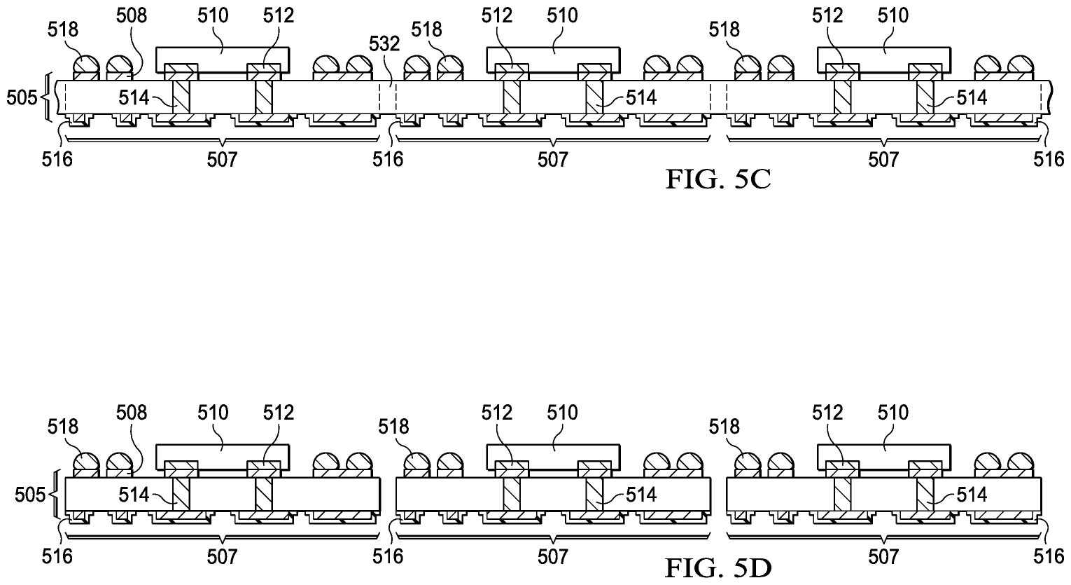

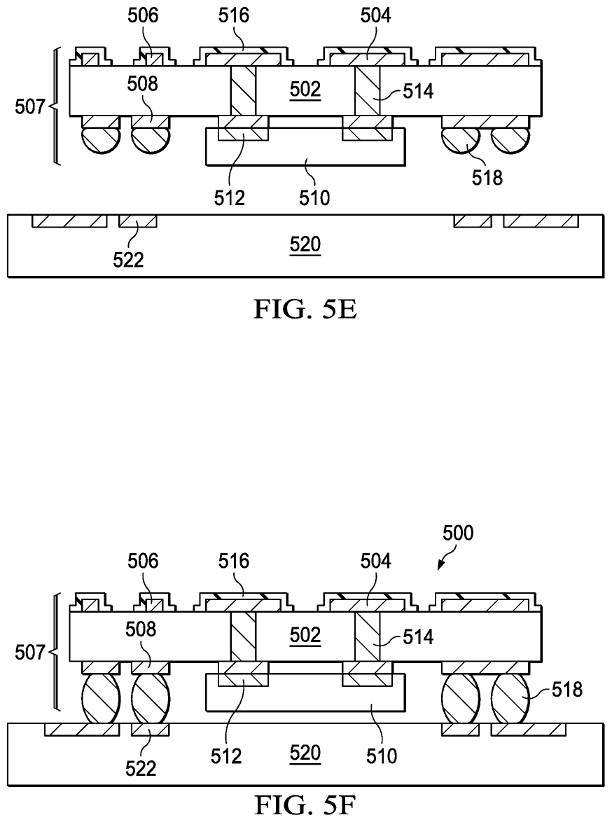

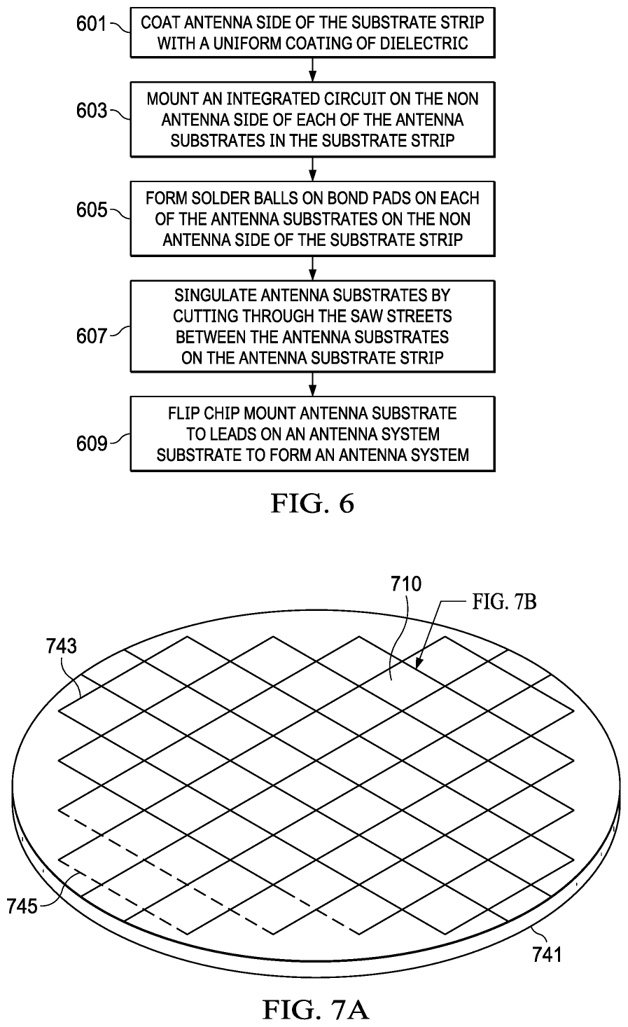

FIGS. 5A-5F are cross sectional views illustrating major steps in the manufacture of the wireless communication system 100 shown in FIG. 1. FIG. 6 is a flow diagram with steps describing the cross sections in FIGS. 5A-5F. In FIGS. 5A-5F, similar reference labels are used for similar elements in FIG. 1, for clarity. For example, antenna substrate 502 in FIGS. 5A-5F corresponds to antenna substrate 102 in FIG. 1.

In FIG. 5A, a semiconductor die 510 is positioned over the non-antenna side of each of the three antenna substrates 502 in the antenna substrate strip 505. Vias 514 couple traces for receiving the terminals of the semiconductor die 510 to the antenna side of the substrate. Vias 514 can be filled or lined with conductor material to electrically connect the dies 510 to the antenna side. The antenna side of the substrate strip 505 is coated (step 601, FIG. 6) with antenna protection layer 516 as described in the flow diagram in FIG. 4 and illustrated in cross section in FIG. 3A.

In FIG. 5B, a semiconductor die 510 is mounted (step 603, FIG. 6) on the non-antenna side of each of the antenna substrates 502 in the antenna substrate strip 505 to form a wireless communication module 507.

In FIG. 5C, solder balls 518 are formed on leads 508 on the non-antenna side of the wireless communication modules 507. (step 605, FIG. 6)

In FIG. 5D, the wireless communication modules 507 are singulated (step 607, FIG. 6) by cutting through the saw streets 532 between the antenna substrates 502 on the antenna substrate strip 505.

In FIG. 5E, one of the singulated wireless communication modules 507 is positioned over a wireless communication substrate 520 with the solder balls 518 on the non-antenna side of the wireless communication module 507 aligned to electrical leads 522 on the wireless communication substrate 520.

In FIG. 5F, the wireless communication module is mounted on the wireless communication substrate 520 to form a wireless communications device or system 500 similar to the wireless communication device 100 shown in FIG. 1.

Each of the singulated wireless communication modules 507 can be mounted on a separate wireless system substrate 520 to form individual wireless communication devices 500. The variation in the thickness of the antenna protection layer 516 across the individual wireless communication systems 500 in a manufacturing run is less than 10%. This reduces the variation in performance between the wireless communication devices 500 in the manufacturing run and reduces the number of wireless communications devices 500 that would be otherwise scrapped because of failure to meet performance specifications.

In addition, the thickness of the antenna protection layer 516 on each of the wireless communications devices 500 can be 2 μm or thicker. The thin antenna protection layer 516 provides less attenuation of the transmitted and received RF signals thus improving the performance of the wireless communication devices 500. Variation in the thickness of the antennal protection layer 516 of 10% or less provides narrow bandwidth spread across the wireless devices.

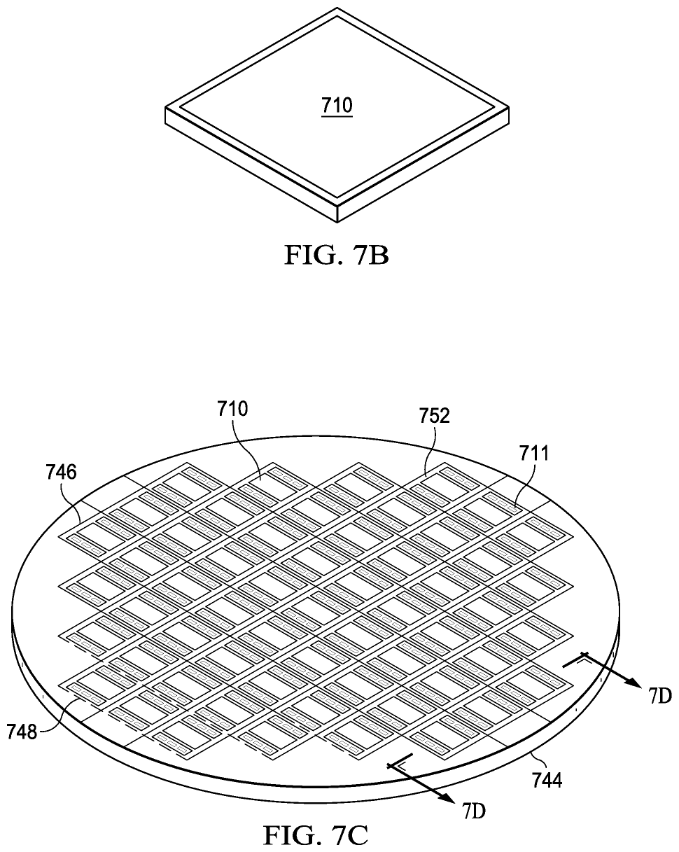

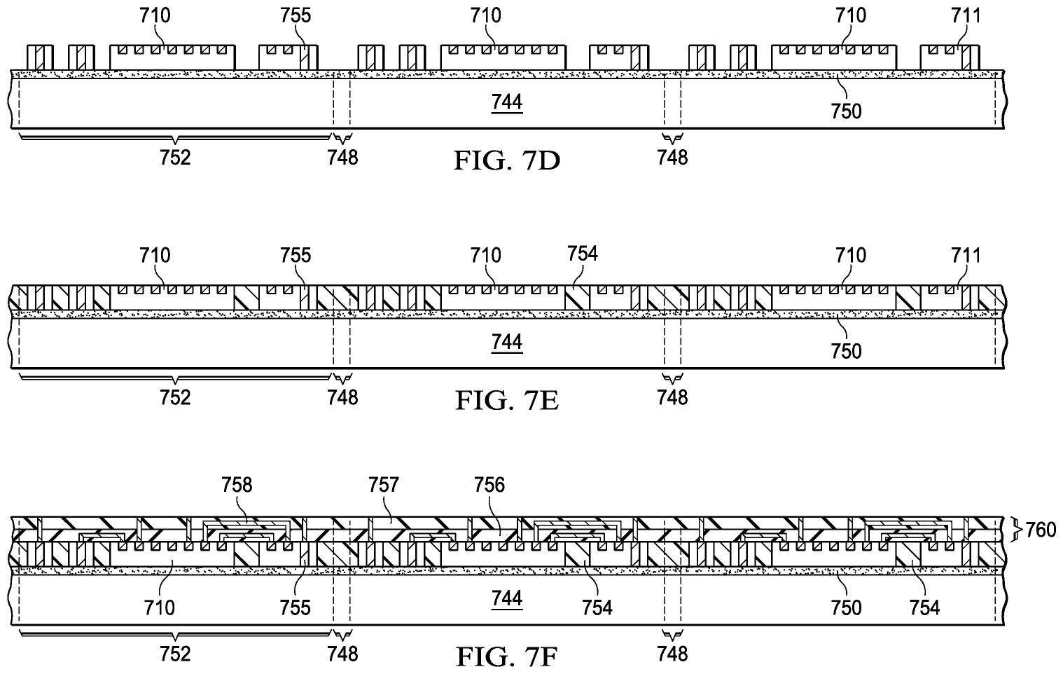

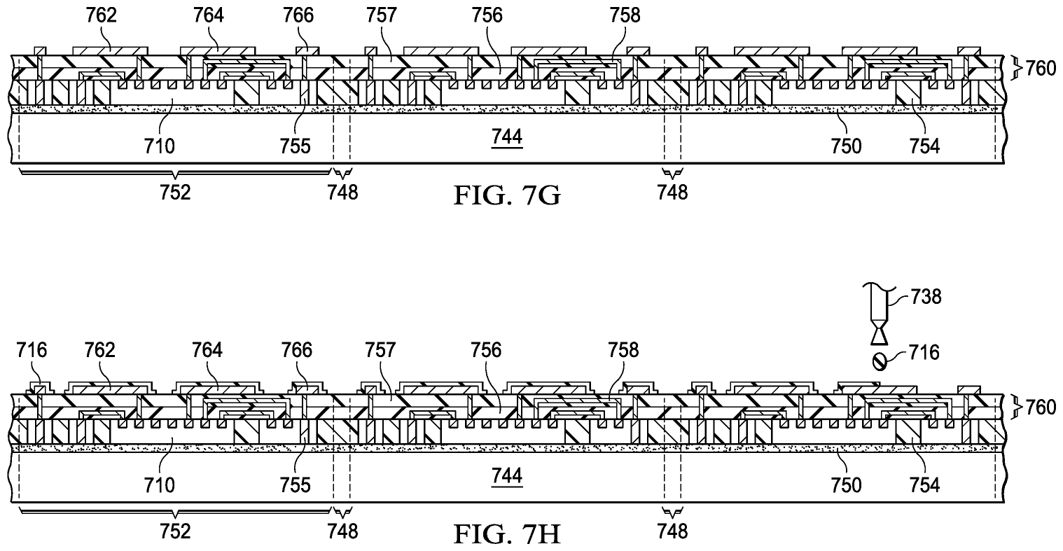

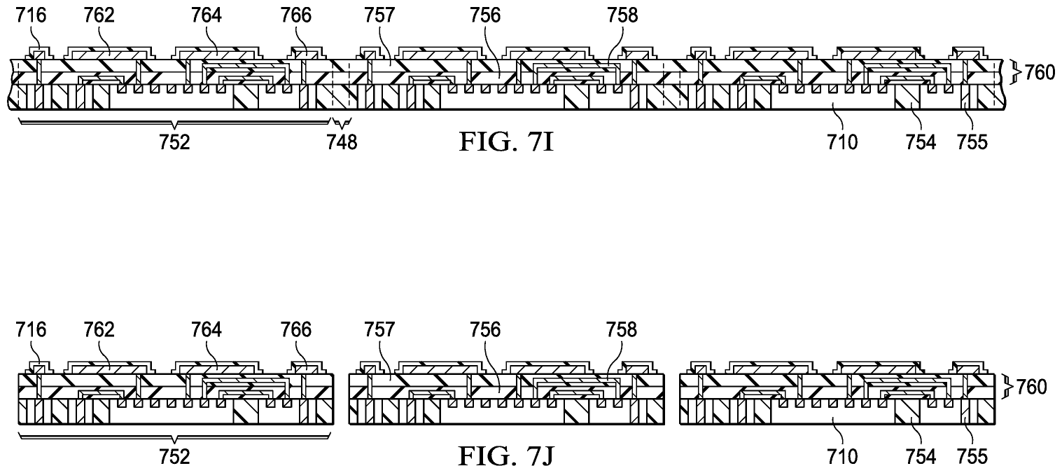

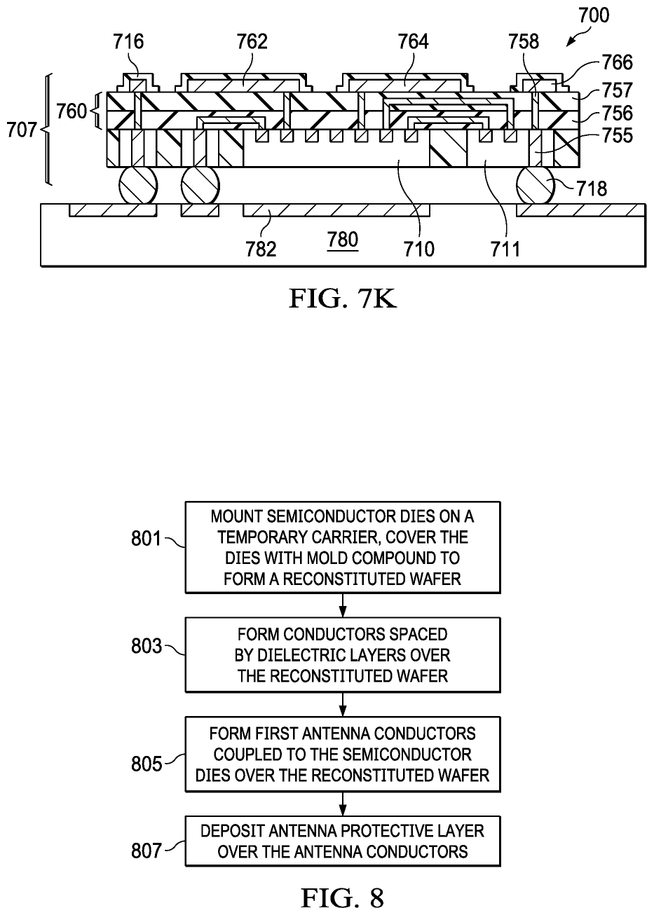

FIGS. 7A-7K illustrate in a series of cross sections the steps for forming an arrangement with a FOWLP packaged wireless communication device 700.

In FIG. 7A, a semiconductor die 710, which can be a wireless semiconductor device corresponding to 510 in FIGS. 5A-5F, for example, is manufactured on a semiconductor wafer 741 using standard integrated circuit manufacturing processes. In FIG. 7B, the semiconductor dies 710 are singulated by cutting through the wafer 741 along the horizontal 743 and vertical 745 scribe lanes that border each semiconductor die 710.

In FIG. 7C is shown in a first step for forming a packaged device 700 with a fan-out wafer level processing (FOWLP) arrangement. In FIG. 7C, the semiconductor dies 710 are positioned on a temporary carrier such as a metal support and bonded to the temporary carrier with an adhesive 750 to form a reconstituted wafer 744. Additional layers of interconnect and antennas can then be formed on the reconstituted wafer 744 using standard integrated circuit processing. Other electrical devices such as electrical feed throughs 755, passive components, and other semiconductor dies 711 can also be processed along with the wireless semiconductor device die 710 on the reconstituted wafer 744 using the FOWLP arrangement.

FIG. 7D shows a cross section view through three of the reconstituted wafer die 752 taken along dashed line D-D′ in FIG. 7C. The reconstituted wafer die 752 are joined together with saw streets 748 between them.

In FIG. 7E, an encapsulation mold compound 754 is applied to fill the spaces on the reconstituted wafer 744 that are between the wireless semiconductor device die 710, the electrical feed throughs 755 and other integrated circuit dies 711 if present.

In FIG. 7F a redistribution layer 760 is shown formed over the circuit side of the semiconductor die 710 and extending away from the semiconductor die 710 and covering portions of the mold compound 754, covering the electrical feed throughs 755, and covering other semiconductor device dies 711 if present. The redistribution layer 760 can be composed of multiple layers, 756 and 757 of a dielectric such as silicon dioxide or polyimide with embedded wires 758. The redistribution layer 760 can be formed using dielectric material and the conductors can be formed using photolithography, electroplating, and metal etch processes. In alternative processes, thin film materials, films and laminates can be used instead to form the redistribution layer 760. In an example fan out wafer level process, the redistribution layer 760 is formed on the reconstituted wafer die 752 including semiconductor die 710 and mold compound 754 using processes similar to those used in semiconductor processing. Steps such as seed layer sputter, photolithography, photoresist deposit, pattern and etch, metal electroplating and metal etch, can be used to deposit conductors 758 in layers of dielectric material 757 and 756, with vertical connections made using vias and fill material in the vias between conductor layers 758. The redistribution layer can be one or more layers of interconnect.

FIG. 7G illustrates in a cross section the reconstituted wafer dies 752 in FIG. 7F with antenna conductors 762 and 764 formed on a surface of the redistribution layer 760. The antenna conductors 762 and 764 are coupled to the semiconductor die 710 by the interconnects 758 through the redistribution layer 760.

FIG. 7H illustrates the reconstituted wafer dies 752 of FIG. G with antenna protection layer 716 deposited over the antenna conductors 762 and 764 and is deposited on about 5 μm of the surface of the redistribution layer 760 surrounding the antenna conductors 762 and 764. The antenna protection layer 716 is also deposited over and about 5 μm around traces 766 on the redistribution layer 760. In an example the antenna protection layer 760 is deposited using ink jet deposition as described above. In a particular example the thickness of the antenna protection layer 716 is about 2 μms+/−0.2 μms. In an example the antenna protection layer 716 is UV curable, and after deposition, is cured by exposure to UV light. In another example the antenna protection layer 716 is cured by thermal processing as is described hereinabove.

In FIG. 71, the temporary substrate 744 and the glue 750 is removed from the non-antenna side of the reconstituted wafer dies 752.

In FIG. 7J the reconstituted wafer dies 752 are singulated by cutting through the horizontal 746 and vertical 748 saw streets between the reconstituted wafer dies 752 to form wireless communication modules 707.

FIG. 7E illustrates in cross section a completed wireless communications device 700 with the antenna protection layer 716 over the antennas 762 and 764 and leads 766. Solder balls 718 are formed on the non-antenna side of the wireless communication module 707 for use in mounting the wireless communication module 707 to a wireless communication system board 780, for example.

FIG. 8 is a flow diagram that illustrates an example method for forming the arrangements as shown in FIGS. 7C-7K. In step 801, semiconductor dies are positioned and mounted on a temporary carrier, and are then covered in mold compound by an encapsulation process to from a reconstituted wafer. In step 803, the redistribution layer is formed over the reconstituted wafer, the redistribution layer including conductors spaced by dielectric layers.

In step 805 antenna conductors are formed over a surface of the redistribution layer. This is shown in FIG. 7G. In step 807, the antenna protection layer is deposited over the second antenna conductors, as shown in FIG. 7H. The antenna protection layer can cover all of or less than all of the surface of the redistribution layer on which the antennas are formed. Processing then continues to complete the devices.

Modifications are possible in the described arrangements, and other alternative arrangements are possible within the scope of the claims.

What is claimed is:

1. A wireless communication device, comprising:
a substrate having an antenna on an antenna side surface;
a semiconductor die on a device side surface of the substrate, opposite the antenna side surface; and
an antenna protection layer covering the antenna and at least a portion of the antenna side surface of the substrate having a predetermined thickness across the antenna side surface of the substrate within +/−10%.

2. The device of claim 1, wherein the antenna protection layer is deposited using ink jet deposition and the predetermined thickness of the antenna protection layer is in a range of 2 μm to 20 μm.

3. The device of claim 1, wherein a thickness of the antenna protection layer is in a range of 2 μm to 100 μm with a uniformity to within +/−0.5 μm.

4. The device of claim 1, wherein the predetermined thickness of the antenna protection layer is 2 μm and is uniform to within +/−0.2 μm.

5. The device of claim 1, wherein the antenna protection layer is one selected from a group consisting essentially of: polyimide, polybenzoxazole, and epoxy.

6. The device of claim 1, and further comprising the substrate being a first substrate that is mounted to a second substrate.

7. The device of claim 6, wherein the first substrate is mounted to the second substrate by solder balls on the device side of the first substrate.

8. The device of claim 1 wherein the substrate is one selected from a group consisting essentially of: a molded interconnect substrate; a pre-molded lead frame with lead frame conductors and mold compound in a preformed structure; a tape based substrate carrying conductors; and film-based substrate carrying conductors; a laminate substrate with multiple layers of conductors and insulator layers; and a printed circuit board substrate of ceramic, fiberglass, epoxy or resin.

9. The device of claim 1, wherein the semiconductor die is a transceiver circuit coupled to the antenna by filled vias and traces on a multi-layer substrate.

10. A wireless communication device, comprising:
an antenna coupled to a wireless communication circuit; and
an antenna protection layer overlying the antenna with a thickness between 2 μm and 20 μm covering the antenna.

11. The wireless communication device of claim 10 wherein the antenna protection layer is deposited using ink jet deposition and a thickness of the antenna protection layer varies by less than +/−.0.2 μm.

12. The wireless communication device of claim 10 further comprising:
the antenna over an antenna side surface of a substrate; and
the substrate is one selected from a group consisting essentially of: a molded interconnect substrate; a pre-molded lead frame with lead frame conductors and mold compound in a preformed structure; a tape based substrate carrying conductors; a film-based substrate carrying conductors; a laminate substrate with multiple layers of conductors and insulator layers; and a printed circuit board substrate of ceramic, fiberglass, epoxy or resin.

13. The wireless communication device of claim 12 further comprising a transceiver semiconductor die mounted on a non-antenna side surface of the substrate that is opposite to the antenna side surface, the transceiver semiconductor die electrically coupled to the antenna.

14. The wireless communication device of claim 12 wherein the substrate is a first substrate and further comprising a second substrate, and the first substrate is mounted on the second substrate.

15. The wireless communication device of claim 14, wherein the first substrate is mounted on the second substrate with ball bonds.

16. The wireless communication device of claim 12, wherein the antenna protection layer is one selected from a group consisting essentially of: polyimide, polybenzoxazole, and epoxy.

17. A method for forming a wireless communication device, comprising:
coating an antenna on an antenna side of a substrate strip with an antenna protection layer, where a thickness of the antenna protection layer is deposited to a predetermined thickness that is uniform to within +/−10%;
singulating antenna substrates from the substrate strip by cutting through saw streets between at least two antenna substrates on the substrate strip; and
coupling the antenna on an antenna substrate to a wireless communication circuit.

18. The method of claim 17, further comprising:
prior to singulating the antenna substrates, forming solder balls on electrical leads on a non-antenna side of the substrate strip that is opposite the antenna side of the substrate strip;
mounting a singulated antenna substrate on a second substrate; and
using the solder balls, forming ball bonds between the electrical leads on the non-antenna side of the antenna substrate and electrical leads on the second substrate.

19. The method of claim 18, further comprising mounting a semiconductor die on the non-antenna side of the antenna substrate and electrically coupling the semiconductor die to the antenna.

20. The method of claim 17, wherein coating an antenna further comprises performing ink jet deposition, and a thickness of the antenna protection layer is uniform to within +/−0.2 μm.

21. The method of claim 17, wherein coating an antenna further comprises performing screen deposition of an ink residue and a thickness of the antenna protection layer is in a range of 10 μm to 20 μm with a uniformity that is +/−1 μm.

22. The method of claim 17, wherein the antenna protection layer is one selected from a group consisting essentially of: polyimide, polybenzoxazole, and epoxy.

23. The method of claim 17, wherein after deposition, the antenna protection layer is cured at a temperature of 150° C.-200° C. for a time greater than zero to up to one hour.

24. The method of claim 17, wherein after deposition, the antenna protection layer is cured using exposure to light.

25. A wireless communication device, comprising:
a semiconductor die having a circuit side on a device side surface of a redistribution layer;
mold compound covering the semiconductor die on a non-circuit side and covering portions of the redistribution layer;
first antenna conductors in the redistribution layer coupled to the semiconductor die;
second antenna conductors over a surface of the mold compound facing away from the redistribution layer; and
an antenna protection layer covering the second antenna conductors having a predetermined thickness across the second antenna conductors within +/−10%.

26. The device of claim 25, wherein the antenna protection layer is deposited using ink jet deposition and the thickness of the antenna protection layer is in a range of 2 μm to 20 μm and is uniform to within +/−0.2 μm.

27. The device of claim 25, wherein a thickness of the antenna protection layer is in a range of 2 μm to 100 μm.

28. The device of claim 25, wherein a thickness of the antenna protection layer is in range of 2 μm to 35 μm.

29. The device of claim 25, wherein the antenna protection layer is selected from a group consisting essentially of: polyimide, polybenzoxazole, and epoxy.

30. The device of claim 25, wherein the semiconductor die is a transceiver circuit.

31. The device of claim 25, wherein the antenna protection layer is screen deposited and has a thickness in a range of 10 μm to 20 μm with a uniformity that is +/−1 μm.
